(19) United States
(12) Patent Application Publication
(10) Pub. No.: US 2025/0113627 A1
(43) Pub. Date: Apr. 3, 2025

(54) HIGH EFFICIENCY QUANTUM DOT IMAGE SENSORS AND METHODS OF FORMING THE SAME

(71) Applicant: Adeia Semiconductor Bonding Technologies Inc., San Jose, CA (US)

(72) Inventors: Rajesh Katkar, Milpitas, CA (US); Belgacem Haba, Saratoga, CA (US); Cyprian Emeka Uzoh, San Jose, CA (US); Oliver Zhao, Daly City, CA (US)

(21) Appl. No.: 18/543,862

(22) Filed: Dec. 18, 2023

Related U.S. Application Data
(60) Provisional application No. 63/541,578, filed on Sep. 29, 2023.

(51) Int. Cl. H01L 27/146; H01L 31/0203; H01L 31/0352; H01L 31/18

(52) U.S. Cl. CPC H10F 39/011; H10F 71/138; H10F 77/1433; H10F 77/50

(57) ABSTRACT

An image sensor using quantum dots is formed that improves collection of photogenerated carrier using a conductive matrix, a semiconductive matrix, a matrix comprising conductive particles and quantum dots in a transparent non-conductive material, conductive structures, and/or porous conductive structures. Hybrid bonding of the image sensor to an image processor device is performed without use of an intervening adhesive to connect the image sensor to the image processor device.

### CROSS-REFERENCE TO RELATED APPLICATION

This application claims the benefit of U.S. Provisional Patent Application No. 63/541,578, filed Sep. 29, 2023, which is hereby incorporated by reference herein in its entirety.

### FIELD

The present disclosure relates to sensors formed using quantum dots (QDs), herein “quantum dot sensors”, and devices including quantum dot sensors, herein “quantum dot sensor devices”, and in particular, high efficiency quantum dot image sensor devices and methods of manufacturing the same.

### SUMMARY

Embodiments herein provide for a quantum dot sensor that improves collection of photogenerated carrier using a conductive matrix, a semiconductive matrix, a matrix comprising conductive particles and quantum dots in a transparent non-conductive material, conductive structures, and/or porous conductive structures. A conductive matrix may comprise quantum dots in a transparent conductive material or quantum dots and conductive particles in a transparent conductive material. Advantageously, the conductive matrix, the semiconductive matrix, the matrix comprising conductive particles and quantum dots in a non-conductive material, conductive structures, and/or the porous conductive structures may help enable a photogenerated carrier to be transported to an electrode to improve efficiency of the quantum dot sensor. The embodiments may enable quantum dot sensors with reduced density of quantum dots, saving on material costs, and reducing the density of quantum dots may enable quantum dot sensors with increased thickness to enable more capturing of light over conventional sensors using quantum dots.

One general aspect includes a method of forming a sensor (e.g., photodiode, light detector, or an image sensor comprising a plurality of sensors) using quantum dots. In some embodiments, the method of forming a sensor comprises forming a conductive matrix, and before or after forming the conductive matrix, forming electrodes. In some embodiments, the conductive matrix may comprise quantum dots in a transparent conductive material layer. In other embodiments, the conductive matrix may comprise quantum dots and conductive particles in a transparent conductive material layer. The transparent conductive material layer may comprise a transparent conductive oxide. In some embodiments, the transparent conductive oxide may comprise metallic oxide(s), for example vanadium oxide or strontium oxide. In some other embodiments, the transparent conductive material layer or particles may comprise a layer such as 50 nm or less, 40 nm or less, 30 nm or less, 20 nm or less, 10 nm or less, 5 nm or less, 3 nm or less, or 2 nm or less of metallic nitride, for example titanium nitride. In some embodiments, the transparent conductive material layer may comprise a doped dielectric layer or a layer such as 50 nm or less, 40 nm or less, 30 nm or less, 20 nm or less, 10 nm or less, 5 nm or less, 3 nm or less, or 2 nm or less of dielectric-metal dielectric laminate D₁MD₂, where D₁ and D₂ may comprise different dielectric layers, having different dielectric constants and different thicknesses. The metal layer M, for example may comprise a layer such as 50 nm or less, 40 nm or less, 30 nm or less, 20 nm or less, 10 nm or less, 5 nm or less, 3 nm or less, or 2 nm or less of silver doped with less than 5% copper, may comprise gold or aluminum amongst others. The dielectric layers D₁ and D₂ may comprise ZnO, TiO₂, Al₂O₃, strontium oxide, or vanadium oxide. The thickness of the oxide layers may vary between about 3 nm to about 30 nm or higher, depending on a thickness to induce electrical conductivity and optical transparency. The dielectric layers may also serve as a protective layer to suppress degradation of the metal layer M. The electrodes may be disposed in electrical communication with the conductive matrix and may be disposed on a same side of the conductive matrix.

In some embodiments, the method of forming a sensor (e.g., photodiode, light detector, or an image sensor comprising a plurality of sensors) comprises forming a matrix, and before or after forming the matrix, forming electrodes. The matrix may comprise conductive particles and quantum dots in a transparent insulating material layer. The electrodes may be disposed in electrical communication with the matrix and may be on a same side of the matrix.

In some embodiments, the method of forming a sensor (e.g., photodiode, light detector, or an image sensor comprising a plurality of sensors) comprises forming a semiconductive matrix, and before or after forming the semiconductive matrix, forming electrodes. In some embodiments, the semiconductive matrix comprises quantum dots in a semiconductive material layer. In other embodiments, the semiconductive matrix may comprise conductive particles and quantum dots in a semiconductive material layer. The electrodes may be disposed in electrical communication with the semiconductive matrix and may be on a same side of the semiconductive matrix.

In some embodiments, the method of forming a sensor (e.g., photodiode, light detector, or an image sensor comprising a plurality of sensors) comprises forming conductive structures (e.g., conductive nano-structures) on a surface of a substrate, and forming a quantum dot layer over the conductive structures. The conductive structures may extend upwardly from the substrate surface and may be electrically coupled to electrodes disposed therein. The conductive structures may comprise wires, nanowires (NW), carbon nano tubes (CNT), conductive pillars, conductive nano pillars, conductive posts, or some combination thereof extending from a surface of the electrodes. The quantum dot layer may comprise quantum dots disposed in a transparent encapsulant. Respective portions of the quantum dot layer may be disposed between adjacent conductive structures.

In some embodiments, the method of forming a sensor (e.g., photodiode, light detector, or an image sensor comprising a plurality of sensors) comprises forming electrodes, forming porous conductive structures, and forming a quantum dot layer. The porous conductive structures may be electrically coupled to the electrodes. The quantum dot layer may be disposed in a transparent encapsulant, and respective portions of the quantum dot layer may be disposed between adjacent conductive features of the porous conductive structures. The porous conductive structures may be transparent or opaque. Each porous conductive structure may comprise a conductive layer with conductive pillars extending from the conductive layer.

In some embodiments, the electrodes of a sensor are bond pads. The electrodes of the sensor may be directly bonded to bond pads of an image processor device. The electrodes may be in a particular shape or arrangement (e.g. interdigitated electrodes, concentric rings, rectangular array when viewed from top down or bottom up).

In some embodiments, the electrodes of a sensor are electrically connected to bond pads via interconnects in the interconnect layer. For example, the electrodes may be on a same side of a conductive matrix. In other examples, the electrodes may be on a same side of a matrix, a semiconductive matrix, or a quantum dot layer instead of a conductive matrix. The electrodes may be in a particular shape or arrangement (e.g. interdigitated electrodes, concentric rings, rectangular array when viewed from top down or bottom up). The bond pads of the sensor may be directly bonded to bond pads of image processor device.

In some embodiments, an electrode of the sensor is a top electrode. The electrodes of the sensor comprise a first and a second electrode. For example, the first electrode is in contact with at least a first surface of a conductive matrix and the second electrode (e.g., top electrode) comprises a transparent conductive material layer in contact with a second surface of the conductive matrix opposite the first surface. The electrodes are electrically connected to bond pads via interconnects in an interconnect layer. In other embodiments, the first electrode may be in contact with at least a first surface of a matrix, a semiconductive matrix, or a quantum dot layer, and the second electrode may be in contact with a second surface of the matrix, the semiconductive matrix, or the quantum dot layer opposite the first surface. In some embodiments, the first electrode may be in a particular shape or arrangement.

In some embodiments, the electrodes of a sensor are electrically connected to electrode contacts through vias in a semiconductor layer, and the electrode contacts are electrically connected to bond pads through interconnects in an interconnect layer. The semiconductor layer may comprise pixel transistors that control electrical signals from pixel sensors of the image sensor.

Another general aspect includes a sensor (e.g., photodiode, light detector, or an image sensor comprising a plurality of sensors). The sensor may be formed using any of the methods described above for forming a sensor.

Another general aspect includes an image sensor device. Generally, the image sensor device includes a sensor (e.g., photodiode, light detector, or an image sensor comprising a plurality of sensors) hybrid bonded to an image processor device. Hybrid bonding may include contacting the sensor with the image processor device to form a workpiece, and heating the workpiece to a temperature less than about 300° C. to connect the bond pads of the sensor and the image processor device. In some embodiments, the contacting the sensor with the image processor device may be performed at ambient temperatures.

### BRIEF DESCRIPTION OF THE DRAWINGS

The above and other objects and advantages of the disclosure will be apparent upon consideration of the following detailed description, taken in conjunction with the accompanying drawings.

FIG. 1A is an illustrative schematic sectional side view of an image sensor with a conductive matrix, in accordance with embodiments of the present disclosure;

FIG. 1B schematically illustrates a hybrid bonding method of an image sensor and an image processor device, in accordance with embodiments of the present disclosure;

FIGS. 2A-2D are illustrative schematic sectional side views of examples of an image sensor with a conductive matrix, in accordance with embodiments of the present disclosure;

FIG. 3A schematically illustrates example configuration of electrodes, in accordance with embodiments of the present disclosure;

FIG. 3B is an illustrative schematic sectional side view of quantum dots deposited in an opening of a substrate that is shaped to enhance light collection, in accordance with embodiments of the present disclosure;

FIG. 4 is an illustrative schematic sectional side view of an image sensor with conductive particles, in accordance with embodiments of the present disclosure;

FIG. 5 is an illustrative schematic sectional side view of an image sensor with conductive nano structures, in accordance with embodiments of the present disclosure; and

FIG. 6 is an illustrative schematic sectional side view of an image sensor with porous conductive structures, in accordance with embodiments of the present disclosure.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein provide for a high efficiency sensor (e.g., photodiode, light detector, or an image sensor comprising a plurality of sensors) using quantum dots. The high efficiency sensor enables collection of photogenerated carriers via a conductive matrix, conductive particles, conductive structures, and/or porous conductive structures, reducing or eliminating the need for a photogenerated carrier on a quantum dot to hop to adjacent quantum dots to reach an electrode.

A quantum dot sensor, such as a photodiode and/or other light detector formed using quantum dots may include electrodes, one or more quantum dot layers, and an encapsulant layer. An image sensor may comprise a plurality of sensors (e.g., sensor pixels, photo sites). An image sensor device may include an image sensor coupled to read-out integrated circuits (ROICs) or an image processor device. Each quantum dot layer may be tuned to absorb light in a desired range of wavelengths by using quantum dots formed of different materials and/or having different sizes. For example, quantum dot materials (e.g., PbS, CdS, CdSe, ZiSe) may have a tunable absorption spectrum to provide image sensing across a range of wavelengths. The material of the quantum dot and the size of the particles can be adjusted to absorb any wavelength of light (e.g. visible and infrared spectrum). Different materials and particle sizes could be further mixed to adjust to wider band of wavelengths. Quantum dot material may be applied by inkjet printing or spin coating from a colloidal solution.

A quantum dot layer may comprise quantum dots in a transparent insulating material (e.g., polymer, encapsulant). Each quantum dot layer may be tuned to absorb light in a desired range of wavelengths by using quantum dots formed of different materials and/or having different sizes. For example, different quantum dots may be used to detect light in a range of infrared (IR) wavelengths (e.g., short wave infrared (SWIR), near IR (NIR) wavelengths) or in different ranges of visible wavelengths (e.g., red, green, and blue wavelengths). Quantum dots may be used to detect light in IR, NIR, SWIR, visible, or any suitable wavelength range.

When a quantum dot in a sensor pixel absorbs a photon, an electron or photogenerated carrier escapes its localized bond. The edge of the quantum dot confines the transport of the electron, but the electron may hop to a neighboring quantum dot if close enough. The electron performs sequential hops between quantum dots until it reaches an electrode of the sensor pixel to be counted by the pixel's readout circuit. A quantum dot layer may be thin to enable a limited number of electron hops before getting counted. However, quantum dot can have defects or imperfections in their crystal lattices because of because of their small size and large surface area. A defective quantum dot along a path for a photogenerated carrier to get to an electrode may cause the photogenerated carriers to recombine before the electron can reach an electrode. A photon absorbed by a quantum dot that generates an electron that recombines on a defective quantum dot is therefore not detected by the pixel circuitry, reducing the signal that reaches an image sensor processor. A few defective quantum dots can affect sensor performance by reducing the collected signal.

To help address the above problems, embodiments herein provide for a sensor (e.g., photodiode, detector, or an image sensor comprising a plurality of sensors) using quantum dots that improves collection of photogenerated carrier using a conductive matrix, a matrix comprising conductive particles and quantum dots in a transparent insulating material layer (e.g., non-conductive transparent material layer), a semiconductive matrix, conductive structures, and/or porous conductive structures. A conductive matrix may comprise quantum dots in a transparent conductive material layer or may comprise quantum dots and conductive particles in a transparent conductive material layer. In some embodiments, the transparent conductive material layer may comprise a transparent conductive oxide, a transparent conductive nitride, a doped dielectric layer or a layer such as 50 nm or less, 40 nm or less, 30 nm or less, 20 nm or less, 10 nm or less, 5 nm or less, 3 nm or less, or 2 nm or less of dielectric-metal dielectric laminate D₁MD₂, where D₁ and D₂ may comprise different dielectric layers, having different dielectric constants and different thicknesses. A conductive matrix, a matrix, a semiconductive matrix, conductive structures, and/or porous conductive structures help enable a photogenerated carrier to be transported to an electrode, reducing or eliminating the need for a photogenerated carrier to hop to adjacent quantum dots to reach an electrode of a photo site to be counted by the readout circuit of the photo site, improving performance of sensor with quantum dots over conventional sensors using quantum dots.

As described below, semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein relate to bonded structures in which two or more elements are directly bonded to one another without an intervening adhesive (referred to herein as “direct bonding”, or “directly bonded”). In some embodiments, direct bonding can involve the bonding of a single material on the first of the two or more elements and a single material on a second one of the two more elements, where the single materials on the different elements may or may not be the same. Direct bonding can also involve bonding of multiple materials on one element to multiple materials on the other element (e.g., hybrid bonding). As used herein, the term “hybrid bonding” refers to a species of direct bonding in which both i) nonconductive features directly bond to nonconductive features, and ii) conductive features directly bond to conductive features.

The hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N2, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes “semiconductor substrates” that provide a supporting material upon which elements of a semiconductor device are fabricated or attached, and any material layers, features, electronic devices, and/or passive devices formed thereon, therein, or therethrough.

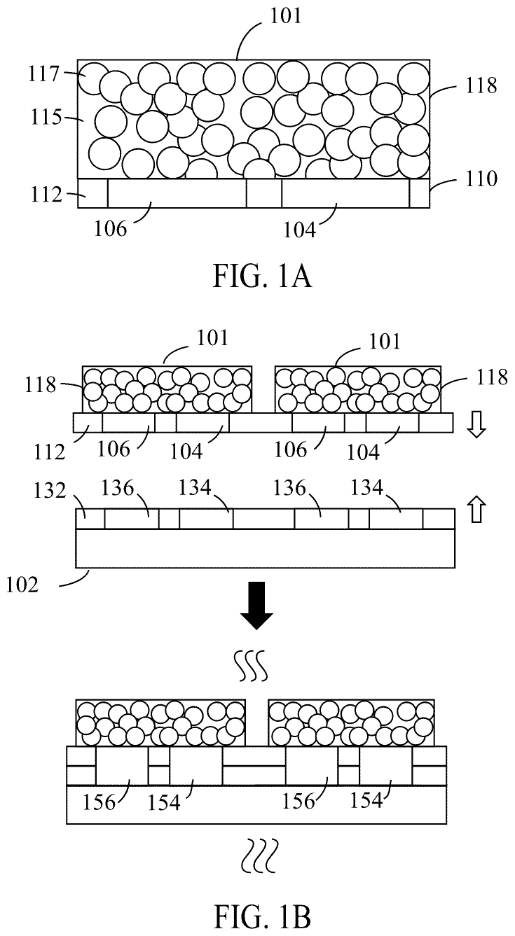

FIG. 1A is an illustrative schematic sectional side view of an image sensor 101 with a conductive matrix 118, in accordance with embodiments of the present disclosure. The image sensor 101 comprises a conductive matrix 118 and electrodes 104 and 106 (e.g., conductive features or bond pads). The electrodes 104 and 106 are disposed in a dielectric layer 112, e.g., SiO2. The image sensor 101 comprises a plurality of sensors (e.g., photodiodes, two or more photodiodes, e.g., thousands of photodiodes, or millions of photodiodes) although one sensor is shown in FIG. 1A.

The conductive matrix 118 comprises a transparent conductive material layer 115 and quantum dots 117 disposed in the transparent conductive material layer 115. The transparent conductive material layer 115 may comprise a transparent conductive oxide and may partially encapsulate the quantum dots 117. The transparent conductive oxide may comprise indium tin oxide (ITO), zinc oxide (ZnO), tin oxide (SnO), aluminum doped zinc oxide (AZO), indium oxide (In2O3), cadmium oxide (CdO), or some combination thereof. The transparent conductive material layer 115 may comprise a transparent conductive oxide or nitride, a doped dielectric layer, a layer of dielectric-metal dielectric laminate, or some combination thereof.

In some embodiments, a method of forming the image sensor 101 comprises forming the conductive matrix 118, and before or after forming the conductive matrix 118, forming the electrodes 104 and 106. For example, the electrodes 104 and 106 may be formed before forming the conductive matrix 118, and the conductive matrix 118 may be deposited on electrodes 104 and 106. In another example, the electrodes 104 and 106 may be formed after forming the conductive matrix 118, and the electrode 104 and 106 may be deposited on the conductive matrix 118. The conductive matrix 118 may be deposited on a substrate prior to electrode deposition, and the image sensor 101 may be transferred to another substrate (e.g., temporary substrate) prior to bonding the electrodes 104 and 106 to bond pads of an image processor device.

In some embodiments, forming the conductive matrix 118 may comprise depositing, by physical vapor deposition, the transparent conductive material layer 115 and depositing, by spin coating, the quantum dots 117. For example, the quantum dots 117 may be deposited by spin coating a colloidal solution of quantum dots. In some embodiments, the quantum dots 117 may be deposited using spray coating.

In some embodiments, forming the conductive matrix 118 may comprise depositing, by physical vapor deposition, the transparent conductive material layer 115 and depositing, by printing, the quantum dots 117. In some embodiments, For example, the quantum dots 117 may be deposited using inkjet printing.

In some embodiments, forming the conductive matrix 118 may comprise repeatedly and sequentially depositing quantum dot layers and transparent conductive material layers. For example, quantum dot layers may be deposited (e.g., by spin coating, spray coating, or inkjet printing), and transparent conductive material layers may be deposited (e.g., by physical vapor deposition).

In some embodiments, forming the conductive matrix 118 may comprise depositing the transparent conductive material layer 115 and the quantum dots 117 from a suspension of quantum dots 117 and transparent conductive material. The suspension may be deposited via spin coating, printing, or spray coating.

In some embodiments, the conductive matrix 118 is patterned. The image sensor 101 comprises a repeating pattern of conductive matrices and corresponding electrodes (shown as one patterned conductive matrix 118 and electrodes 104 and 106).

In some embodiments, the conductive matrix 118 may be formed patterned (e.g., printed). For example, using inkjet printing, a specific amount of quantum dot material (e.g. size, shape, volume, material type, etc.) may be directly deposited to pixel locations to form individual pixels. In some embodiments, a specific amount of a suspension of quantum dots material and transparent conductive material may be directly deposited to pixel locations to form individual pixels.

In some embodiments, the transparent conductive material layer 115 may be patterned when deposited (e.g., using a shadow mask). In some embodiments, the transparent conductive material layer 115 may be deposited in a continuous layer and patterned after deposition (e.g., using photolithography).

In other embodiments, the conductive matrix 118 may be formed as a continuous layer and the continuous layer may be patterned to effectively form separate pixels. For example, the conductive matrix 118 may be patterned using photolithography.

In some embodiments, a semiconductive matrix may be formed instead of a conductive matrix 118. For example, the image sensor 101 of FIG. 1A may not comprise a conductive matrix 118 and instead comprise a semiconductive matrix. A semiconductive matrix may comprise quantum dots 117 disposed in a transparent semiconductive material layer instead of a transparent conductive material layer 115. In some embodiments, a transparent semiconductive material layer may comprise semiconducting oxides.

The electrodes 104 and 106 are disposed in electrical communication with the conductive matrix 118. The electrodes 104 and 106 may comprise any suitable conductive material (e.g., metal). The electrodes 104 and 106 may be on a same side of the conductive matrix 118. In some embodiments, the electrodes 104 and 106 and/or the dielectric layer 112 are chemically mechanically polished (CMP). For example, electrodes 104 and 106 may be formed by depositing a layer of conductive material, such as copper, on a substrate comprising the dielectric layer 112 having openings formed therein and removing an overburden of the conductive material using a CMP process. In some embodiments, the electrodes may be formed by depositing the electrodes 104 and 106 in openings of the dielectric layer 112 formed to expose portions of the conductive matrix 118. In some embodiments, the electrodes may be formed by depositing the layer of conductive material on a substrate comprising the dielectric layer 112 patterned to expose portions of the conductive matrix 118, and removing an overburden of the conductive material using a CMP process.

In some embodiments, a graphene sheet or layer may be formed between the electrodes and the conductive matrix to improve carrier transport. For example, a graphene sheet may be formed between the electrodes 104 and 106 the conductive matrix 118.

In some embodiments, an optional electron transport layer (ETL, e.g., TiOx, ZnO) or a hole transport layer (e.g., p-type polymer) may be deposited between the electrodes 104 and 106 and the conductive matrix 118 to improve carrier transport and injection.

In some embodiments, at least one transparent conductive layer is embedded within the conductive matrix 118. One or more transparent conductive layers may be one or more electrodes.

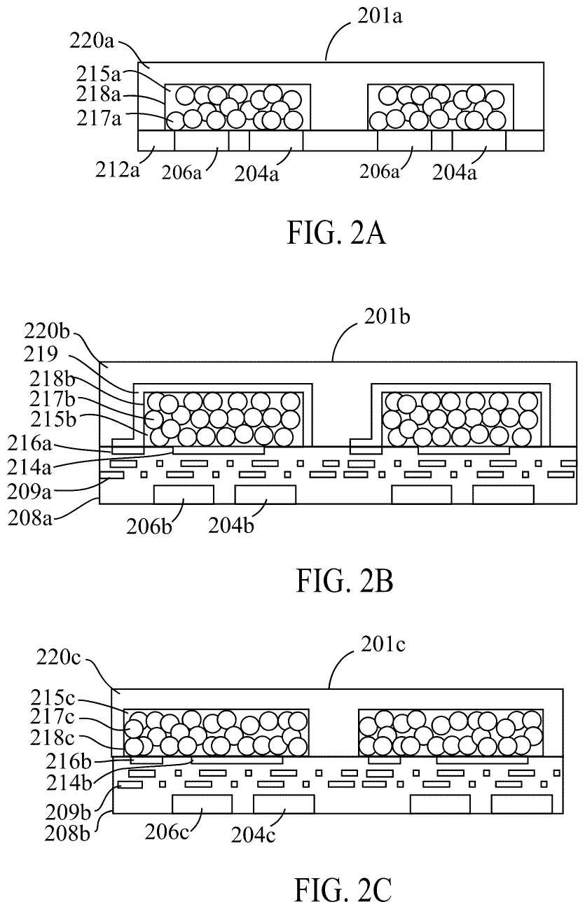

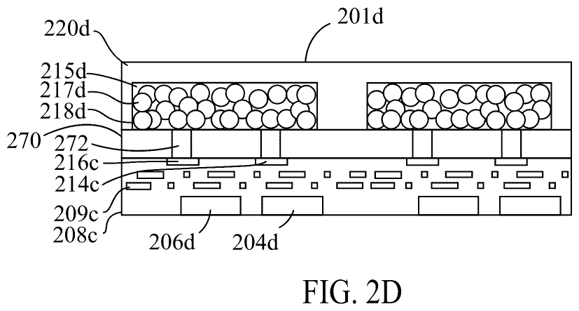

In some embodiments, a dielectric layer may be formed on the conductive matrix 118. For example, instead of no dielectric layer formed on the conductive matrix 118 in FIG. 1A, a dielectric layer as described in relation to FIG. 2A (e.g., dielectric layer 220a) may be formed on the conductive matrix 118.

In some embodiments, the electrodes 104 and 106 of FIG. 1A may be electrically connected to bond pads via interconnects in an interconnect layer. For example, the electrodes 104 and 106 of FIG. 1A may not comprise bond pads and may instead be electrically connected to bond pads (e.g., bond pads 204b and 206b) via interconnects (e.g., interconnects 209a) in an interconnect layer (e.g., interconnect layer 208a) as described in relation to FIG. 2B. In some embodiments, the electrodes 104 and 106 and conductive matrix 118 may be adjacent to a semiconductor layer that is adjacent to an interconnect layer. For example, the electrodes 104 and 106 of FIG. 1A may not comprise bond pads and instead be electrically connected to electrode contacts (e.g., electrode contacts 214c and 216c) through vias (e.g., vias 272) in the semiconductor layer (e.g., semiconductor layer 270) as described in relation to FIG. 2D. For example, the semiconductor layer (e.g., semiconductor layer 270) may comprise pixel transistors that control electrical signals from pixel sensors of the image sensor, and the electrode contacts may be electrically connected to bond pads (e.g., bond pads 204d and 206d) through interconnects (e.g., interconnects 209c) in the interconnect layer (e.g., interconnect layer 208c) as described in relation to FIG. 2D.

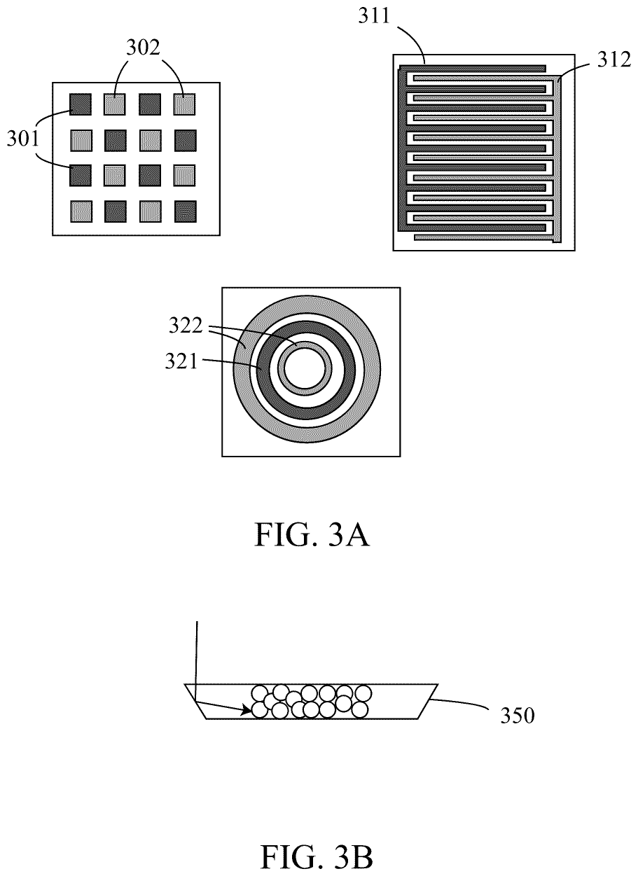

In some embodiments, the electrodes 104 and 106 may be comprise the electrode arrangements shown in FIG. 3A. For example, the electrodes 104 and 106 may comprise a rectangular array comprising alternating first electrodes (e.g., electrodes 301) and second electrodes (e.g., electrodes 302) as described in relation to FIG. 3A. For example, the electrodes 104 and 106 may comprise a first electrode (e.g., electrode 311) and a second electrode (312) interdigitated with the first electrode as described in relation to FIG. 3A. For example, the electrodes 104 and 106 may comprise alternating concentric rings of one or more first electrodes (e.g., electrode 321) and second electrode (e.g., electrode 322) when viewed from top down or bottom up as described in relation to FIG. 3A. Although a few variations of electrode placements are shown in FIG. 3A, any suitable placement of electrodes and distribution of first electrodes 301 and second electrodes 302 can be provided that could generate uniform electric field to move the photogenerated carriers to respective electrode(s).

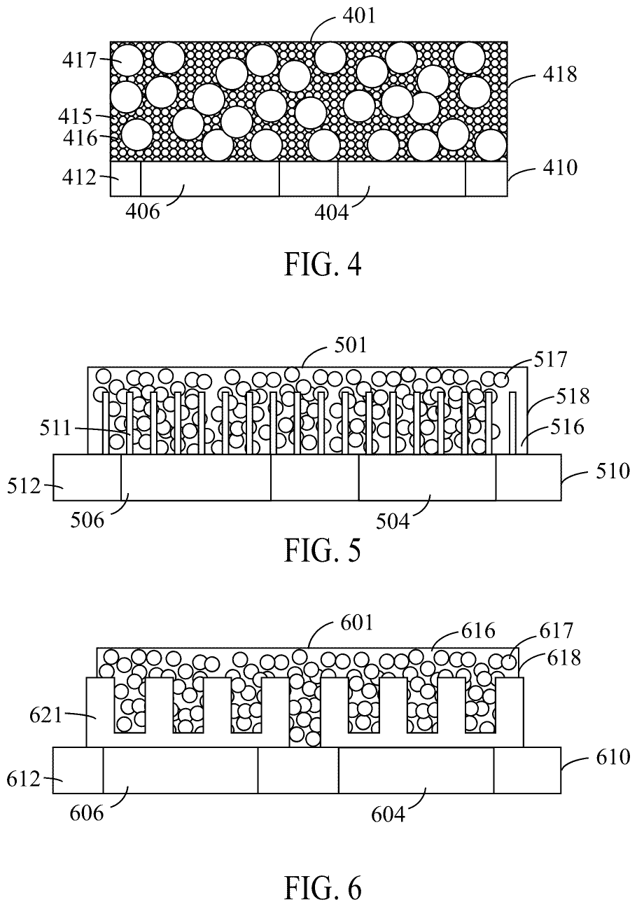

In some embodiments, the conductive matrix 118 may comprise conductive particles in the transparent conductive material layer 115. For example, the conductive particles may be similar to the ones described in FIG. 4 (e.g., embodiment with conductive particles 415 embedded in a transparent material layer 416 that is a transparent conductive material layer).

FIG. 1B schematically illustrates a hybrid bonding method of an image sensor 101 and an image processor device 102, in accordance with embodiments of the present disclosure. The method includes aligning the bond pads (e.g., electrodes 104 and 106) of the image sensor 101 with the bond pads 134 and 136 of the image processor device 102 and contacting the image sensor 101 and the image processor device 102. In some embodiments, contacting the image sensor 101 and the image processor device 102 may be performed at ambient temperatures. Here, contacting the image sensor 101 and image processor device 102 forms a workpiece where the image sensor 101 and the image processor device 102 are attached to one another through direct bonds formed between the dielectric layers 112 and 132 without the use of an intervening adhesive. The method includes heating the workpiece to a processing temperature between about 50° C. to about 150° C. or more, or of about 150° C. or more, such as about 250° C. or more, or about 300° C. or more, or to a temperature less than about 300° C., or less than about 250° C., to form direct interconnects 154 and 156 via hybrid bonding of the bond pads (e.g., electrodes 104 and 106) of the image sensor 101 to bond pads 134 and 136 of the image processor device 102. For example, hybrid bonding may comprise directly bonding the bond pads (e.g., electrodes 104 and 106) of the image sensor 101 to the bond pads 134 and 136 of the image processor device 102. FIG. 1B shows an example of an image sensor 101 with two sensor pixels (e.g., sensors, photodiodes). However, any suitable number of sensor pixels may be used (e.g., one, two or more, e.g. thousands, or millions).

In some embodiments, the hybrid bonding method of an image sensor 101 and an image processor device 102 as described in relation to FIG. 1B may be applied to image sensors described in embodiments of this disclosure. For example, the image sensor 101 may be replaced with image sensor 201a, 201b, 201c, or 201d of FIG. 2A-2D, image sensor 401 of FIG. 4, image sensor 501 of FIG. 5, image sensor 601 of FIG. 6, or any suitable image sensor embodiment described in this disclosure.

FIG. 2A is an illustrative schematic sectional side view of an image sensor 201a with a conductive matrix 218a, in accordance with embodiments of the present disclosure. As shown in FIG. 2A, the conductive matrix 218a is be patterned. Image sensor 201a comprises electrodes 204a and 206a in a first dielectric layer 212a, conductive matrix 218a on the electrodes 204a and 206a, and a second dielectric layer 220a. The conductive matrix 218a comprises quantum dots 217a in a transparent conductive material layer 215a The image sensor 201a may be substantially similar to the image sensor 101 as described above in relation to FIG. 1A, except that a second dielectric layer 220a is formed on the conductive matrix 118 and portions of the dielectric layer 112. The image sensor 201a of FIG. 2A shows an example of two sensor pixels (e.g., photodiodes) instead of the example of a single sensor pixel shown in FIG. 1A.

The method may include depositing a second dielectric layer 220a on the conductive matrix 218a. The second dielectric layer 220a may serve as a barrier or encapsulation layer to protect the quantum dots from oxidation. The second dielectric layer 220a may comprise an oxide material. The second dielectric layer 220a may comprise a material transparent to wavelengths to be detected by the image sensor 201a (e.g., infrared (IR), near IR (NIR), short wave IR (SWIR), visible, or any suitable wavelength range). For example, if the image sensor 201a detects short wave infrared (SWIR) wavelengths, the second dielectric layer 220a may be transparent to wavelengths of the SWIR range. If the image sensor 201a detects a visible range, the second dielectric layer 220a may be transparent to wavelengths in the visible range. In some embodiments, the second dielectric layer 220a may comprise two or more dielectric layers. In other embodiments, additional sealing layer may be deposited (e.g. for further mechanical or environmental protection). For example, the second dielectric layers may comprise one or more layers of silicon oxide, silicon nitride, etc. In some embodiments, the dielectric layers may be polished after deposition to form non-wavy (e.g., smooth) top surface for further deposition of other layers or devices (e.g. polymer lenses, color filters, infrared filters, etc.). In some embodiments, other layers or devices may be formed overlaying second dielectric layer(s) 220a.

In some embodiments, a sealing/barrier film is used in place of the second dielectric layer 220a. The sealing film may comprise a conductive oxide material (e.g., indium tin oxide, indium, zinc, or tin oxide), an oxide material (e.g., aluminum oxide, silicon dioxide), a polymer material, or some combination thereof. For example, the sealing film may comprise alternating inorganic and polymer layers and may provide additional protection against environmental exposure (e.g. oxidation, humidity, etc.) and/or mechanical protection. In some embodiments, the second dielectric layer 220a or sealing/barrier film is optional. For example, the transparent conductive material layer 215a may protect the quantum dots 217a from oxidation. As another example, the conductive matrix 218a may comprise conductive particles in a transparent insulating material layer (e.g., polymer) instead of transparent conductive material layer 215a, and the transparent insulating material layer may protect the quantum dots from environmental exposure.

FIG. 2B is an illustrative schematic sectional side view of an image sensor 201b with a conductive matrix 218b, in accordance with embodiments of the present disclosure. The image sensor 201b comprises an interconnect layer 208a comprising bond pads 204b and 206b, interconnects 209a disposed in an insulating material, and electrodes 214a and 216a, a conductive matrix 218b, top electrode (e.g., transparent conductive layer 219), and a dielectric layer 220b. The conductive matrix 218b comprises quantum dots 217b in a transparent conductive material layer 215b. The image sensor 201b may be substantially similar to the image sensor 201a described above in relation to FIG. 2A, except the sensor 201b includes the interconnect layer 208a and the top electrode (e.g., transparent conductive layer 219). The top electrode (e.g., transparent conductive layer 219) is electrically connected to electrode 216a. The dielectric layer 220b may be substantially similar to the dielectric layer 220a of FIG. 2A except it is on the top electrode (e.g., transparent conductive layer 219) and portions of the interconnect layer 208a. In some embodiments, the image sensor 201b may not include a dielectric layer 220b.

In some embodiments, a sealing/barrier film is used in place of the dielectric layer 220b. The sealing film may comprise a conductive oxide material (e.g., indium tin oxide, indium, zinc, or tin oxide), an oxide material (e.g., aluminum oxide, silicon dioxide), a polymer material, or some combination thereof. For example, the sealing film may comprise alternating inorganic and polymer layers and may provide additional protection against environmental exposure (e.g. oxidation, humidity, etc.) and/or mechanical protection. In some embodiments, the dielectric layer 220b or sealing/barrier film is optional. For example, the transparent conductive material layer 215b may protect the quantum dots 217b from environmental exposure. As another example, the conductive matrix 218b may comprise conductive particles in a transparent insulating material layer (e.g., polymer) instead of transparent conductive material layer 215b, and the transparent insulating material layer may protect the quantum dots from environmental exposure.

The electrodes 214a and 216a are electrically connected to bond pads 204b and 206b, respectively, via interconnects 209a in the interconnect layer 208a. In some embodiments, a first electrode 214a is a negative electrode and a second electrode 216a is a positive electrode. In some embodiments, the first electrode 214a and the second electrode 216a are planar to a surface of the interconnect layer 208a. In some embodiments, the second electrode 216a further comprises the transparent conductive layer 219. The first electrode 214a is in contact with at least a portion of a first surface of the conductive matrix 218b, and the second electrode 216a (e.g., further comprising the transparent conductive layer 219) is in contact with a second surface of the conductive matrix 218b opposite the first surface.

A method of forming the image sensor 201b may comprise depositing a top electrode (e.g., transparent conductive layer 219) on the conductive matrix 218b and the second electrode 216a. The transparent conductive layer 219 is patterned. For example, the transparent conductive layer 219 may be deposited and patterned (e.g., via photolithography). The transparent conductive layer 219 may be patterned when deposited (e.g., via a shadow mask). The transparent conductive layer 219 is electrically connected to the second electrode 216a, and the transparent conductive layer 219 may be referred to as an electrode or a top electrode of the sensor 201b. In some embodiments, the transparent conductive layer 219 comprises a transparent conductive oxide material (e.g., ITO).

In some embodiments, an electron transport layer (e.g., TiOx, ZnO) and/or a hole transport layer (e.g., p-type polymer) may be deposited between the respective electrodes and the conductive matrix to improve carrier transport and injection. For example, in a sensor with a top electrode, a hole transport layer may be deposited between a transparent top electrode (electrically connected to electrode 216b) and the conductive matrix 218b and an electron transport layer may be deposited between electrode 214b and the conductive matrix 218b.

In some embodiments, only one of the electrodes of a sensor may comprise first electrodes of FIG. 3A. For example, the electrodes 214a of the sensor 201b of FIG. 2B may comprise first electrodes 301, 311, or 321 of FIG. 3A.

FIG. 2C is an illustrative schematic sectional side view of an image sensor 201c with a conductive matrix 218c, in accordance with embodiments of the present disclosure. The image sensor 201c comprises an interconnect layer 208b comprising bond pads 204c and 206c, interconnects 209b in an insulating material, and electrodes 214b and 216b, a conductive matrix 218c, and a dielectric layer 220c. The conductive matrix 218c comprises quantum dots 217c in a transparent conductive material layer 215c. The image sensor 201c may be substantially similar to the image sensor 201a described above in relation to FIG. 2A, except the image sensor 201c includes an interconnect layer 208b. The interconnect layer 208b may be similar to the interconnect layer 208a described above in relation to FIG. 2B. The conductive matrix 218c may be formed on both electrodes 214b and 216b. No top electrode may be connected to electrode 216b. The dielectric layer 220c may be similar to the dielectric layer 220a, except it is on portions of the interconnect layer 208b instead portions of a first dielectric layer 212a. In some embodiments, the image sensor 201c may not include a dielectric layer 220c.

In some embodiments, a sealing/barrier film is used in place of the dielectric layer 220c. The sealing film may comprise a conductive oxide material (e.g., indium tin oxide, indium, zinc, or tin oxide), an oxide material (e.g., aluminum oxide, silicon dioxide), a polymer material, or some combination thereof. For example, the sealing film may comprise alternating inorganic and polymer layers and may provide additional protection against environmental exposure (e.g. oxidation, humidity, etc.) and/or mechanical protection. In some embodiments, the dielectric layer 220c or sealing/barrier film is optional. For example, the transparent conductive material layer 215c may protect the quantum dots 217c from environmental exposure. As another example, the conductive matrix 218c may comprise conductive particles in a transparent insulating material layer (e.g., polymer) instead of transparent conductive material layer 215c, and the transparent insulating material layer may protect the quantum dots from environmental exposure.

FIG. 2D is an illustrative schematic sectional side view of an image sensor 201d with a semiconductor layer 270, in accordance with embodiments of the present disclosure. The image sensor 201d comprises a conductive matrix 218d and electrodes adjacent to a semiconductor layer 270 that is adjacent to an interconnect layer 208c. The conductive matrix 218d comprises quantum dots 217d in a transparent conductive material layer 215d. The electrodes may be electrically connected to electrode contacts 214c and 216c through vias 272 in a semiconductor layer 270. The semiconductor layer 270 comprises pixel transistors that control electrical signals from pixel sensors of the image sensor 201d. The electrode contacts 214c and 216c are electrically connected to bond pads 204d and 206d through interconnects 209c in the interconnect layer 208c.

In some embodiments, the image sensor 201d may be substantially similar to the image sensor 201c described above in relation to FIG. 2C, except that image sensor 201d includes a semiconductor layer 270 and the interconnect layer 208c comprises electrode contacts 214c and 216c (e.g., instead of electrodes 214b and 216b of the interconnect layer 208b). For example, the image sensor 201d may include electrodes in contact with the conductive matrix 218d (e.g., similar to the electrodes 214b and 216b of FIG. 2C except the semiconductor layer 270 comprises the electrodes). The dielectric layer 220d may be similar to the dielectric layer 220a, except it is on portions of the semiconductor layer 270 instead of portions of a first dielectric layer 212a. In some embodiments, the image sensor 201d may not include a dielectric layer 220d.

In some embodiments, the conductive matrix 218d is formed on the semiconductor layer 270d providing pixel transistors between the conductive matrix 218d comprising quantum dots 217d and the bond pads 204d and 206d. The conductive matrix 218d comprising the quantum dots 217d may act as the photodiodes (i.e. convert photons to electrical signals) and pixel transistors on the semiconductor layer 270 (e.g. silicon) may control the electrical signals. The charge created by a photo-detector may be converted to a voltage signal and may be passed on to the output amplifier through an array of row-select and column-select switches. Furthermore, an analog to digital convertor (ADC) may be formed on the semiconductor layer 270 to digitize the amplified signal. To perform readout, the pixel values of a given row may be transferred in parallel to a set of storage capacitors and then, these transferred pixel values may be read out sequentially. While the conductive matrix 218d comprising quantum dots 217d may only perform the photodetection function, the semiconductor layer(s) 270 may perform the rest of the operation. The semiconductor layer may provide the pixel circuits comprising amp transistors, select transistors, reset transistors, signal lines, ADC, pixel select switches (or row/column selects), memory blocks, capacitors, etc. to form an image sensor circuit with the conductive matrix 218d comprising quantum dots 217d.

The pixel sensor architecture may be one of several types. In an active-pixel sensor (APS) architecture, each pixel location contains not only the photodiode but also an amplifier. A simpler architecture like passive-pixel sensor (PPS) may also be implemented within the semiconductor layer that does not integrate an amplifier into each pixel. In a digital-pixel sensor (DPS) device architecture, each pixel may have its own analog-to-digital converter and memory block which allows the digital values proportional to light intensity.

In some other embodiments, pixel transistors may be a part of an image processor device. For example, pixel transistors may be part of an image processor device 102 of FIG. 1B.

In some embodiments, a sealing/barrier film is used in place of the dielectric layer 220d. The sealing film may comprise a conductive oxide material (e.g., indium tin oxide, indium, zinc, or tin oxide), an oxide material (e.g., aluminum oxide, silicon dioxide), a polymer material, or some combination thereof. For example, the sealing film may comprise alternating inorganic and polymer layers and may provide additional protection against environmental exposure (e.g. oxidation, humidity, etc.) and/or mechanical protection. In some embodiments, the dielectric layer 220d or sealing/barrier film is optional. For example, the transparent conductive material layer 215d may protect the quantum dots 217d from environmental exposure. As another example, the conductive matrix 218d may comprise conductive particles in a transparent insulating material layer (e.g., polymer) instead of transparent conductive material layer 215d, and the transparent insulating material layer may protect the quantum dots from environmental exposure.

FIG. 3A schematically illustrates example configuration of electrodes, in accordance with embodiments of the present disclosure. For example, the electrodes 104 and 106 of the image sensor 101 of FIGS. 1A-1B, the electrodes 204a and 206a of image sensor 201a of FIG. 2A, the electrodes 214b and 216b of image sensor 201c of FIG. 2C, the electrodes of image sensor 201d of FIG. 2D, the electrodes 404 and 406 of image sensor 401, the electrodes 504 and 506 of image sensor 501, or the electrodes 604 and 606 of image sensor 601, may comprise the electrodes 301 and 302, 311 and 312, or 321 and 322 of FIG. 3A. The distribution of first and second electrodes of FIG. 3A may enable creation of a uniform field for carriers to move efficiently.

In some embodiments, the plurality of first electrodes 301 and second electrodes 302 are in a rectangular array. Each electrode may be arranged in an alternating pattern of first and second electrodes when viewed from the top down or bottom up. The first electrodes 301 may be biased with an opposite bias of the second electrodes 302. For example, first electrodes 301 may be biased with a positive bias, and the second electrodes 302 may be biased with a negative bias. In some embodiments, the first electrodes 301 are electrically connected to a first bond pad (e.g., bond pad 204b, 204c, or 204d), and the second electrodes 302 are electrically connected to a second bond pad (e.g., bond pad 206b, 204c, or 206d) through interconnects (e.g., interconnects 209a, 209b, 209c) in an interconnect layer (e.g., interconnect layer 208a, 208b, or 208c) as described above in reference to FIGS. 2B-2D, so that each bond pad is connected to a plurality of electrodes. In this way, a uniform period distribution of electrodes may create a uniform field for carriers to move efficiently. Any suitable number of first electrodes 301 and second electrodes 302 may be used (one or more first electrodes 301 and/or one or more second electrodes 302) and can be formed in any uniform or non-uniform distribution. In FIG. 2D, the bond pads are electrically connected to the electrodes also through vias 272 in a semiconductor layer 270 and electrode contacts 214c and 216c.

In some embodiments, the first electrode 311 and the second electrode 312 are interdigitated electrodes. The first electrode 311 may be biased with an opposite bias of the second electrode 312. The first electrode 311 may be biased with a positive bias, and the second electrode may be biased with a negative bias.

In some embodiments, one or more first electrodes 321 and one or more second electrodes 322 are in a shape of concentric rings. The first electrode 321 may be biased with an opposite bias of the second electrodes 322. The first electrode 321 may be biased with a positive bias, and the second electrode 322 may be biased with a negative bias.

In FIG. 3A, one first electrode 321 and two second electrodes 322 are shown. In some embodiments, the first electrode 321 is electrically connected to the first bond pad (e.g., bond pad 204c or 204d) and the two second electrodes 322 are electrically connected to the second bond pad (e.g., bond pad 206c or 206d) as described in relation to FIGS. 2B-2D. However, any suitable number of first electrodes 321 and second electrodes 322 may be used (one or more first electrodes 321 and/or one or more second electrodes 322) and can be formed in any uniform or non-uniform distribution.

FIG. 3B is an illustrative schematic sectional side view of quantum dots deposited in an opening 350 of a substrate that is shaped to enhance light collection, in accordance with embodiments of the present disclosure. The opening 350 is shaped a way to enhance light collection, as shown by the example light ray depicted. The example light ray is shown to reflect off a side of the opening 350 to be directed towards the quantum dots in the opening 350. For example, patterned conductive matrices (e.g., shown as one patterned conductive matrix 118 of FIGS. 1A-1B, and two patterned conductive matrices 218a-218d in FIGS. 2A-2D) may be formed in an opening 350 in a substrate to enhance light collection.

As an example, in some embodiments, a dielectric layer may be formed on electrodes (e.g., electrodes 104 and 106) in a dielectric layer (e.g., dielectric layer 112) as described in relation to FIGS. 1A-1B. The dielectric layer may be etched in a manner to create openings in a shape of the cross section as shown in FIG. 3B and to expose surfaces of the electrodes (e.g., electrodes 104 and 106). In some embodiments, a conductive matrix (e.g., conductive matrix 218c) may be deposited in the openings formed in the dielectric layer. In some embodiments, a dielectric layer or sealing layer may be deposited on the conductive matrix (e.g., conductive matrix 218c) and the dielectric layer. In some embodiments, a semiconductive matrix or a matrix (e.g., matrix 418) may be used in place of the conductive matrix (e.g., the conductive matrix 118). In some embodiments, a mirror coating or reflective coating may be deposited on the inner sidewalls of an opening 350 to reflect light towards the quantum dots.

As another example, a dielectric layer may be formed on an interconnect layer (e.g., interconnect layer 208b) as described in relation to FIG. 2C, etched in a manner to create openings in a shape of the cross section as shown in FIG. 3B and to expose electrodes (e.g., electrodes 214b and 216b), and a conductive matrix (e.g., conductive matrix 218c) may be deposited in the openings formed in the dielectric layer. In some embodiments, a dielectric layer or sealing layer may be deposited on the conductive matrix (e.g., conductive matrix 218c) and the dielectric layer. In some embodiments, a semiconductive matrix or a matrix (e.g., matrix 418) may be used in place of the conductive matrix (e.g., conductive matrix 218c).

In another example, a dielectric layer may be formed on a semiconductor layer (e.g., semiconductor layer 270) as described in FIG. 2D, etched in a manner to create openings in a shape of the cross section as shown in FIG. 3B and to expose electrodes as described above in relation to FIG. 2D, and a conductive matrix (e.g., conductive matrix 218d) may be deposited in the openings formed in the dielectric layer. In some embodiments, a dielectric layer or sealing layer may be deposited on the conductive matrix (e.g., conductive matrix 218d) and the dielectric layer. In some embodiments, a semiconductive matrix or a matrix (e.g., matrix 418) may be used in place of the conductive matrix (e.g., conductive matrix 218d).

In some embodiments, an electron transport layer (e.g., TiOx, ZnO) or a hole transport layer (e.g., p-type polymer) may be deposited between respective electrodes and a matrix to improve carrier transport and injection. For example, in an image sensor with a matrix a top electrode (e.g., similar to FIG. 2B except conductive matrix 218b is replaced with matrix 418), a hole transport layer may be deposited between a transparent top electrode (e.g., transparent conductive layer 219) and the matrix 418 and an electron transport layer may be deposited between electrode 214a and the matrix 418. In some embodiments, a graphene sheet or layer may be formed between the electrodes and the matrix to improve carrier transport. For example, a graphene sheet may be formed between the electrodes (e.g., electrodes 404 and 406) the matrix (e.g., matrix 418).

FIGS. 4, 5, and 6 show different embodiments of image sensors (e.g., image sensor 401, 501, and 601) having electrodes (e.g., electrodes 404 and 406, 504 and 506, 604 and 606) as bond pads. Similar to how image sensor 101 can be modified to result in different embodiments of image sensors (e.g., image sensors 201a, 201b, 201c, and 201d), the image sensors 401, 501, and 601 can be modified to result in different embodiments of image sensors corresponding to image sensor 201a (e.g., sensor with a top dielectric layer), image sensor 201b (e.g., sensor with a top electrode), image sensor 201c (e.g., sensor with electrodes connected to bond pads via interconnects in an interconnect layer), image sensor 201d (e.g., sensor with electrodes electrically connected to electrode contacts through vias in a semiconductor layer that are electrically connected to bond pads through interconnects in an interconnect layer).

FIG. 4 is an illustrative schematic sectional side view of an image sensor 401 with conductive particles 415, in accordance with embodiments of the present disclosure. The image sensor 401 comprises a matrix 418 with conductive particles 415 on electrodes 404 and 406 in a dielectric layer 412. A substrate 410 comprises the electrodes 404 and 406 embedded in the dielectric layer 412. The matrix 418 comprises conductive particles 415, quantum dots 417, and a transparent material layer 416. In some embodiments, a dielectric layer or sealing layer may be deposited on the matrix 418. The image sensor 401 comprises a plurality of sensors (e.g., photodiodes, two or more photodiodes, e.g., thousands of photodiodes, or millions of photodiodes) although one sensor is shown in FIG. 4.

In some embodiments, a method of forming the image sensor 401 comprises forming the matrix 418, and before or after forming the matrix 418, forming the electrodes 404 and 406. In some embodiments, forming the matrix 418 may comprise forming a matrix comprising conductive particles 415 and quantum dots 417 embedded in a transparent material layer 416. In some embodiments, the transparent material layer 416 is a transparent conductive material layer, a transparent insulating material layer, or a transparent semiconductive material layer.

In some embodiments, the transparent material layer 416 is substantially similar to the transparent conductive material layer 115 described above in relation to FIG. 1A. For example, the matrix 418 may be a conductive matrix similar to the conductive matrix 118, except it further comprises conductive particles 415. The matrix 418 may comprise quantum dots 417 and conductive particles 415 embedded in a transparent conductive material layer (e.g., transparent conductive material layer 115) as described above in relation to FIG. 1A. The conductive particles 415 may transfer the photogenerated charges to the conductive matrix, other conductive particles 415, or quantum dots 417.

In some embodiments, forming the matrix 418 comprises depositing transparent material, conductive particles 415, and quantum dots 417 from a suspension of transparent material (e.g., transparent conductive material, transparent semiconductive material, or transparent non-conductive material), conductive particles 415, and quantum dots 417. The suspension may be deposited via spin coating, printing, or spray coating. The matrix 418 may be patterned. The image sensor 401 may comprise a repeating pattern of matrices (shown as a single patterned matrix 418) and corresponding electrodes 104 and 106. The matrix may be formed patterned (e.g., printed). The matrix 418 may be formed as a continuous layer and the continuous layer may be patterned. For example, the matrix 418 may be patterned using photolithography.

In some embodiments, the transparent material layer 416 is a transparent insulating material layer. The transparent material layer 416 may be a transparent encapsulant. For example, the transparent insulating material may be a polymer. The matrix 418 may comprise quantum dots 417 and conductive particles 415 embedded in a transparent insulating material layer. The conductive particles 415 may transfer the photogenerated charges to other conductive particles 415 or quantum dots 417. The conductive particles 415 may assist in carry the photogenerated charges to the electrodes 404 and 406.

In some embodiments, conductive particles 415 (e.g., comprising ITO material) and quantum dots 417 may be added to a polymer, dispersed using sonication, and/or distributed via spin-coating. For example, conductive particles 415 and quantum dots 417 may dispersed in a polymer using sonication, and spin coated on a substrate 110. In some embodiments, the spun coated film of conductive particles 415 and quantum dots 417 may be patterned. In some embodiment, the conductive particles 415 and quantum dots 417 may be printed.

The conductive particles 415 may comprise any suitable conductive material (e.g., metal, transparent conductive oxide). For example, the conductive material may comprise indium tin oxide, graphite, copper, aluminum, gold, silver, platinum, palladium, or some combination thereof. The conductive particles 415 may be transparent. In some embodiments, the conductive particles 415 comprise a reflective surface.

The conductive particles 415 may be substantially smaller in size compared to quantum dots 417. For example, a ratio of a mean diameter of the quantum dots 417 to a mean diameter of the conductive particles 415 may be greater than about 100, than about 50 or than about 10.

FIG. 5 is an illustrative schematic sectional side view of an image sensor 501 with conductive structures 511 (e.g., conductive nano-structures), in accordance with embodiments of the present disclosure. The image sensor 501 comprises conductive structures 511, a quantum dot layer 518, and electrodes 504 and 506. The quantum dot layer 518 comprises quantum dots 517 in a transparent insulating material 516. The transparent insulating material 516 may be a transparent encapsulant. In some embodiments, the quantum dot layer 518 comprises quantum dots 517. In some embodiments, a dielectric layer or sealing layer may be deposited on the quantum dot layer 518. The image sensor 501 comprises a plurality of sensors (e.g., photodiodes, two or more photodiodes, e.g., thousands of photodiodes, or millions of photodiodes) although one sensor is shown in FIG. 5.

In some embodiments, a method of forming the image sensor 501 comprises forming the conductive structures 511 on a surface of a substrate 510 and forming a quantum dot layer 518 over the conductive structures 511. The conductive structures 511 may extend upwardly from the substrate surface and may be electrically coupled to electrodes 504 and 506 disposed in the substrate 510. Respective portions of the quantum dot layer 518 may be disposed between adjacent conductive structures 511.

In some embodiments, forming the conductive structures 511 comprise growing the conductive structures from a surface of the substrate 510. The conductive structures 511 may grow from a surface of the electrodes 504 and 506. The electrodes 504 and 506 are disposed in electrical communication with conductive structures 511.

The conductive structures 511 may grow from a surface of the dielectric layer 512. In some embodiments, the conductive structures 511 extend from the electrodes 504 and 506 and do not extend from the dielectric layer 512. The electrodes 504 and 506 may be bond pads.

The conductive structures 511 may comprise wires, nanowires, carbon nano tubes, conductive pillars, conductive nanopillars, conductive posts, or some combination thereof extending from a surface of the electrodes 504 and 506. For example, a nanowire array may be grown from a surface of the substrate 510. The diameter of nanowires or nanopillars may be a few nanometers.

In some embodiments, forming the quantum dot layer 518 comprises depositing a suspension comprising quantum dots 517 on the conductive structures 511. In some embodiments, the suspension comprises quantum dots 517 and transparent insulating material 516 (e.g., a polymer, encapsulant). In some embodiments, the suspension comprises quantum dots 517, and the quantum dot layer 518 may comprise quantum dots 517.

In some embodiments, the image sensor 501 comprises a repeating pattern of quantum dot layers 518, conductive structures 511, and corresponding electrodes 504 and 506. In some embodiments, the quantum dot layer 518 may be formed patterned via inkjet printing. In some embodiments, the quantum dot layer 518 may be deposited as a continuous layer (e.g., spin coating, spray coating) and then patterned (e.g., via photolithography).

FIG. 6 is an illustrative schematic sectional side view of an image sensor 601 with porous conductive structures 621, in accordance with embodiments of the present disclosure. The image sensor 601 comprises porous conductive structures 621, a quantum dot layer 618, and electrodes 604 and 606. A substrate 610 may comprise the electrodes 604 and 606 embedded in a dielectric layer 612. The quantum dot layer 618 may comprise quantum dots 617 in a transparent insulating material layer 616 (e.g., polymer, encapsulant). In some embodiments, the quantum dot layer 618 comprises quantum dots 617. In some embodiments, a dielectric layer or sealing layer may be deposited on the quantum dot layer 618. The image sensor 601 comprises a plurality of sensors (e.g., photodiodes, two or more photodiodes, e.g., thousands of photodiodes, or millions of photodiodes) although one sensor is shown in FIG. 6.

In some embodiments, a method of forming the image sensor 601 comprises forming the electrodes 604 and 606, forming the porous conductive structures 621, and forming the quantum dot layer 618. In some embodiments, forming a porous conductive structure 621 comprises forming a conductive layer and growing conductive structures from the conductive layer. In some embodiments, forming the porous conductive structure 621 comprises forming a conductive layer and etching openings in the conductive layer. The openings may be partially etched in the conductive layer so that a continuous portion of the conductive layer remains in the porous conductive structure 621.

The porous conductive structures 621 may be transparent or opaque. Each porous conductive structure 621 may comprise a conductive layer (e.g., plate, continuous layer of conductive material) with pillars formed on the conductive layer. The conductive layer and/or pillars may be formed of a conductive material. The conductive material may be a transparent conductive material (e.g., transparent conductive oxide). The conductive material may be an opaque conductive material (e.g., metal). The conductive material may be an alloy of copper nanoparticles, nanocopper, CNT, and/or copper. The conductive material may comprise nanoparticles in a copper alloy. Nanoparticles may improve conductivity within a copper alloy. The conductive material may comprise CNT incorporated in a transparent conductive material to improve the conductivity of the transparent conductive material.

The electrodes 604 and 606 are disposed within a dielectric layer 612. The electrodes 604 and 606 may be bond pads. The porous conductive structures 621 are electrically coupled to the electrodes 604 and 606. For example, first and second porous conductive structures 621 are electrically coupled to electrodes 604 and 606, respectively.

In some embodiments, forming the quantum dot layer 618 comprises depositing a suspension comprising quantum dots 617 and transparent insulating material (e.g., a polymer, encapsulant) on the porous conductive structures 621. In some embodiments, the suspension comprises quantum dots 617, and the quantum dot layer 618 may comprise quantum dots 617.

In some embodiments, the image sensor 601 comprises a repeating pattern of quantum dot layers 618, porous conductive structures 621, and corresponding electrodes 604 and 606. In some embodiments, the quantum dot layer 618 may be formed patterned via inkjet printing. In some embodiments, the quantum dot layer 618 may be deposited as a continuous layer (e.g., spin coating, spray coating) and then patterned (e.g., via photolithography).

In embodiments where the substrates are bonded using hybrid dielectric and metal bonds, the method may further include planarizing or recessing the metal features below the field surface before contacting and bonding the dielectric material layers. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features. Suitable direct dielectric and hybrid bonding technologies that may be used to perform aspects of the methods described herein include ZiBond® and DBI®, each of which are commercially available from Adeia, San Jose, CA, USA.

It is contemplated that any combination of the methods described above may be used to form an image sensor or image sensor device whether or not expressly recited herein.

The embodiments discussed above are intended to be illustrative and not limiting. One skilled in the art would appreciate that individual aspects of the image sensor, image sensor device, and methods discussed herein may be omitted, modified, combined, and/or rearranged without departing from the scope of the claimed subject matter. Only the claims that follow are meant to set bounds as to what the claimed subject matter includes.

1. A method of forming an image sensor comprising a conductive matrix and electrodes disposed in electrical communication with the conductive matrix, the method comprising:
forming the conductive matrix, the conductive matrix comprising a transparent conductive material layer and quantum dots disposed in the transparent conductive material layer; and
before or after forming the conductive matrix, forming the electrodes, wherein the electrodes are disposed on a same side of the conductive matrix.

2. The method of claim 1, wherein the transparent conductive material layer comprises a transparent conductive oxide.

3. The method of claim 2, wherein the transparent conductive oxide comprises indium tin oxide, zinc oxide, tin oxide, aluminum doped zinc oxide, indium oxide, cadmium oxide, or some combination thereof.

4. The method of claim 2, wherein the transparent conductive oxide at least partially encapsulates the quantum dots.

5. The method of claim 1, wherein forming the conductive matrix comprises:
depositing, by physical vapor deposition, the transparent conductive material layer; and
depositing, by spin coating, the quantum dots.

6. The method of claim 1, wherein forming the conductive matrix comprises:
depositing, by physical vapor deposition, the transparent conductive material layer; and
depositing, by printing, the quantum dots.

7. The method of claim 1, wherein forming the conductive matrix comprises:
patterning the transparent conductive material layer and the quantum dots disposed in the transparent conductive material layer.

8. The method of claim 1, wherein forming the conductive matrix comprises:
repeatedly and sequentially depositing quantum dot layers and transparent conductive material layers.

9. The method of claim 1, wherein the conductive matrix further comprises conductive particles in the transparent conductive material layer.

10. The method of claim 1, wherein the image sensor comprises a repeating pattern of conductive matrices and corresponding electrodes.

11. The method of claim 1, further comprising forming a dielectric layer on the conductive matrix.

12. The method of claim 1, wherein the electrodes comprise bond pads disposed in a dielectric layer.

13. The method of claim 1, wherein:
the electrodes are electrically connected to bond pads via interconnects in an interconnect layer.

14. The method of claim 1, wherein:
the conductive matrix and the electrodes are adjacent to a semiconductor layer that is adjacent to an interconnect layer;
the electrodes are electrically connected to electrode contacts through vias in the semiconductor layer;
the semiconductor layer comprises pixel transistors that control electrical signals from pixel sensors of the image sensor; and
the electrode contacts are electrically connected to bond pads through interconnects in the interconnect layer.

15. The method of claim 14, wherein:
the electrodes comprise a rectangular array comprising alternating first electrodes and second electrodes.

16. The method of claim 15, wherein the first electrodes are biased with an opposite bias of the second electrodes.

17. The method of claim 14, wherein:
the electrodes comprise a first electrode and a second electrode interdigitated with the first electrode.

18. The method of claim 14, wherein:
the electrodes comprise alternating concentric rings of one or more first electrodes and second electrodes when viewed from top down or bottom up.

19-23. (canceled)

24. The method of claim 9, wherein a ratio of a mean diameter of the quantum dots to a mean diameter of the conductive particles is greater than about 10.

25. The method of claim 9, wherein the conductive particles comprise a reflective surface.

26-116. (canceled)
